(19) United States
(12) Patent Application Publication
(10) Pub. No.: US 2024/0371430 A1
(43) Pub. Date: Nov. 7, 2024

(54) SERIALIZER CLOCKING SCHEME FOR A MEMORY DEVICE

(71) Applicant: MICRON TECHNOLOGY, INC., BOISE, ID (US)

(72) Inventor: Jongtae Kwak, Boise, ID (US)

(73) Assignee: MICRON TECHNOLOGY, INC., BOISE, ID (US)

(21) Appl. No.: 18/653,768

(22) Filed: May 2, 2024

Related U.S. Application Data
(60) Provisional application No. 63/500,525, filed on May 5, 2023.

(51) Int. Cl. G11C 11/4076; H03K 3/037; H03K 19/20

(52) U.S. Cl. CPC G11C 11/4076; H03K 3/037; H03K 19/20

(57) ABSTRACT

A semiconductor device may include a serializer circuit configured to generate an output clock signal for serialization. The serializer circuit may include a clock generator circuit configured to generate the output clock signal based on an input clock signal. Both the input and output clock signals may be multi-phase clock signals. The clock generator circuit may include an input clock buffer circuit, inverter circuits, a clock pulse circuit (e.g., a plurality of NAND gates in a configuration), and phase splitter circuits arranged in a configuration so as to reduce current leakage and allow for a smaller footprint, among other benefits. The clock generator circuit may provide the output clock signal to a serializer included in the serializer circuit for serialization.

### CROSS-REFERENCE TO RELATED APPLICATION(S)

This application claims the filing benefit of U.S. Provisional Application No. 63/500,525, filed May 5, 2023. This application is incorporated by reference herein in its entirety and for all purposes.

### BACKGROUND

A memory device may serialize data in various situations, such as for storage or transmission of the data. Serializing may include converting complex data structures, such as objects or arrays, into a format (e.g., a series of bytes) that may be more easily stored or transmitted. The memory device may generate clock signals for serialization. The memory device may provide serialized data at a timing dictated by the generated clock signals.

### BRIEF DESCRIPTION OF DRAWINGS

FIG. 1 is a block diagram of a semiconductor device according to some embodiments of the disclosure.

FIG. 2 is a block diagram of a serializer circuit according to some embodiments of the disclosure.

FIG. 3 is a schematic diagram of a clock generator circuit according to some embodiments of the disclosure.

FIG. 4 is a timing diagram of signals according to some embodiments of the disclosure.

FIG. 5 is a schematic diagram of a serializer circuit according to some embodiments of the disclosure.

FIG. 6 is a schematic diagram of an internal clock generator according to some embodiments of the disclosure.

### DETAILED DESCRIPTION

Various embodiments of the present disclosure will be explained below in detail with reference to the accompanying drawings. The following detailed description refers to the accompanying drawings that show, by way of illustration, specific aspects in which embodiments of the present disclosure may be practiced. These embodiments are described in sufficient detail to enable those skilled in the art to practice the embodiments of present disclosure. Other embodiments may be utilized, and structure, logical and electrical changes may be made without departing from the scope of the present disclosure. The various embodiments disclosed herein are not necessary mutually exclusive, as some disclosed embodiments can be combined with one or more other disclosed embodiments to form new embodiments.

Certain details are set forth below to provide a sufficient understanding of embodiments of the disclosure. However, it will be clear to one skilled in the art that embodiments of the disclosure may be practiced without these particular details. Moreover, the particular embodiments of the present disclosure described herein are provided by way of example and should not be used to limit the scope of the disclosure to these particular embodiments. In other instances, well-known circuits, control signals, timing protocols, and software operations have not been shown in detail in order to avoid unnecessarily obscuring embodiments of the disclosure. Additionally, terms such as “couples” and “coupled” mean that two components may be directly or indirectly electrically coupled. Indirectly coupled may imply that two components are coupled through one or more intermediate components.

A memory device may serialize data in various situations, such as for storage or transmission of the data, using a serializer circuit. Serializing may include converting complex data structures, such as objects or arrays, into a format (e.g., a series of bytes) that may be more easily stored or transmitted. The serializer may include a clock generator circuit and a serializer circuit. The serializer may receive clock signals (e.g., from an internal clock generator), and the clock generator circuit may both generate (e.g., adjust or modify) and provide clock signals to the serializer circuit based on the received clock signals. The serializer circuit may provide serialized data at a timing dictated by the generated clock signals.

However, current clock generator circuits for serializer circuits may be inefficient (e.g., high current leakage, large footprint). It may be desirable to design a new clock generator circuit.

The present disclosure provides examples of a clock generator circuit for a serializer circuit. The clock generator circuit may include an input clock buffer circuit, one or more inverter circuits, a clock pulse circuit, and one or more phase splitter circuits. The input clock buffer circuit may be coupled to the inverter circuits, the inverter circuits may be coupled to the clock pulse circuit, and the clock pulse circuit may be coupled to the phase splitter circuits. The input clock buffer circuit may receive divided clock signals from an internal clock generator (e.g., a clock divider circuit), may stabilize, preserve, or otherwise “clean up” the received clock signals to maintain accurate synchronization and coordination for time-sensitive operations, and may provide the clock signals to the one or more inverter circuits. The one or more inverter circuits (e.g., NOT gates) may invert the clock signals, and may provide the inverted clock signals to the clock pulse circuit. The clock pulse circuit may include various circuitry configured to adjust or modify various aspects of the clock signals (e.g., pulse width) and inverted clock signals, and may provide the adjusted or modified clock signals (e.g., clock pulses) to the one or more phase splitter circuits. The one or more phase splitter circuits may each receive an adjusted or modified clock signal, and generate two output clock signals with equal amplitude but opposite phases (true and bar signals). These output clock signals may be provided to a serializer circuit, where serialized data is provided at a timing based on these output clock signals. Such a configuration for the clock generator circuit may result in one or more benefits, including lower current leakage and a smaller footprint, among other benefits, resulting from fewer circuit elements (e.g., NAND gates, inverters) being included due to a different configuration of the circuit elements compared to previous solutions.

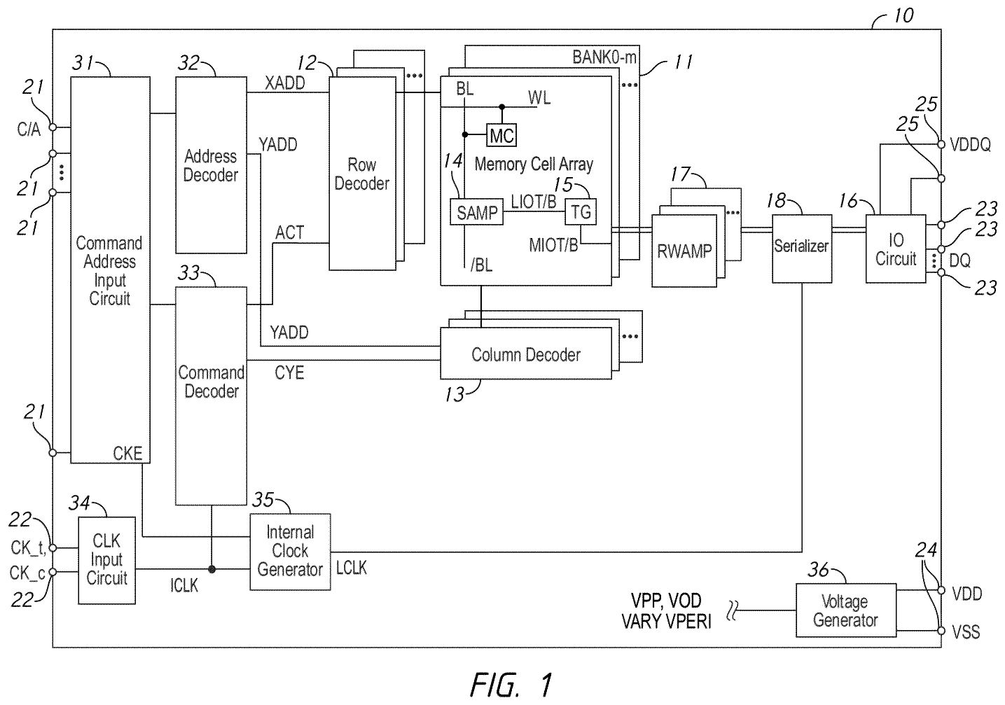

FIG. 1 is a block diagram of a semiconductor device 10 according to some embodiments of the present disclosure. The semiconductor device 10 can be, for example, a dynamic random access memory (DRAM) incorporated into a single semiconductor chip. As shown in FIG. 1, the semiconductor device 10 includes a memory cell array 11. The memory cell array 11 includes a plurality of word lines WL, a plurality of bit lines BL and /BL, and a plurality of memory cells MC respectively provided at intersections between the word lines WL and the bit lines BL or/BL. Selection of the word lines WL is performed by a row decoder 12 and selection of the bit lines BL and /BL is performed by a column decoder 13. A sense amplifier 14 is coupled to a corresponding one of the bit lines BL or /BL and a local I/O line pair LIOT/B. The local I/O line pair LIOT/B is coupled to a main I/O line pair MIOT/B via a transfer gate 15. The memory cell array 11 is divided into m+1 memory banks including memory banks BANK0 to BANKm.

A plurality of external terminals included in the semiconductor device 10 include a command address terminals 21, clock terminals 22, data terminals 23, and power terminals 24, 25. The data terminal 23 is coupled to an I/O circuit 16.

Command address signals CA are supplied to the command address terminals 21. Signals related to an address in the command address signals CA supplied to the command address terminal 21 is transferred to an address decoder 32 via a command address input circuit 31, and signals related to a command are transferred to a command decoder 33 via the command address input circuit 31. The address decoder 32 decodes the address signal to generate a row address XADD and a column address YADD. The row address XADD is supplied to the row decoder 12 and the column address YADD is supplied to the column decoder 13. A clock enable signal CKE is supplied to an internal clock generator 35.

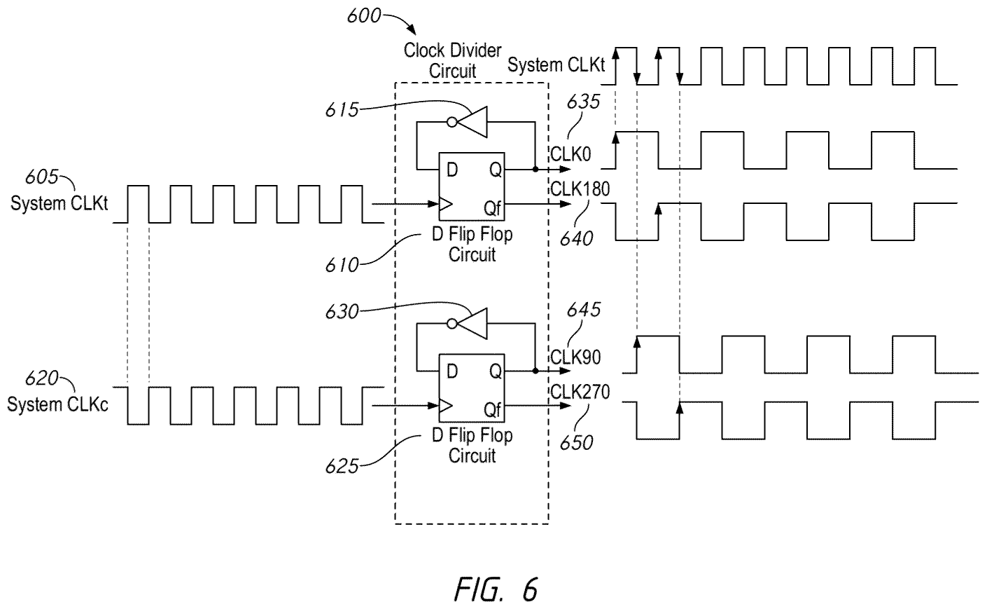

Complementary external clock signals CK_t and CK_c are supplied to the clock terminal 22. The complementary external clock signals CK_t and CK_c are input to a clock input circuit 34. The clock input circuit 34 generates an internal clock signal ICLK based on the complementary external clock signals CK_t and CK_c. The internal clock signal ICLK is supplied to at least the command decoder 33 and the internal clock generator 35. The internal clock generator 35 is activated, for example, by the clock enable signal CKE and generates an internal clock signal LCLK based on the internal clock signal ICLK. The internal clock signal LCLK is supplied to serializer 18, and/or the I/O circuit 16. In some cases, the internal clock signal LCLK may be used as a timing signal for timing when read data DQ is to be output from the data terminal 23 in a read operation. In some other cases, the internal clock signal LCLK may be used as a timing signal that the serializer circuit 18 uses to generate clock signals for serialized data output. In some cases, internal clock generator 35 may include a clock divider. A clock divider may be an electronic circuit that generates an output clock signal with a lower clock frequency than its input clock signal (e.g., using flip-flops, counters, or the like). In some embodiments of the disclosure, the internal clock generator 35 may provide a multi-phase clock signal (e.g., a 4-phase clock signal). Clock dividers may be described in further detail in at least FIG. 6.

In a write operation, write data may be input from outside to the data terminal 23.

Power potentials VDD and VSS are supplied to the power terminal 24. These power potentials VDD and VSS are supplied to a voltage generator 36. The voltage generator 36 generates various internal potentials VPP, VOD, VARY, VPERI, and the like based on the power potential VDD and VSS. The internal potential VPP is mainly used in the row decoder 12, the internal potentials VOD and VARY are mainly used in the sense amplifiers 14 included in the memory cell array 11, and the internal potential VPERI is used in other circuit blocks.

Power potentials VDDQ and VSS are supplied from the power terminal 25 to the I/O circuit 16. Although the power potentials VDDQ can be same as the power potential VDD supplied to the power terminal 24, respectively, dedicated power potential VDDQ are allocated to the I/O circuit 16 to prevent power-supply noise that occurs in the I/O circuit 16 from propagating to other circuit blocks.

The command decoder 33 activates an active signal ACT when an active command is issued. The active signal ACT is supplied to the row decoder 12. When a read command or a write command is issued from outside following the active command, the command decoder 33 activates a column selection signal CYE. The column selection signal CYE is supplied to the column decoder 13 and a corresponding one or more of the sense amplifiers 14 is selected to provide data. Accordingly, read data is read from the memory cell array 11 in the read operation. The read data having been read from the memory cell array 11 is transferred to the I/O circuit 16 via a read/write amplifier 17 and a serializer circuit 18, and is output from the data terminal 23 to outside. In the write operation, write data having been input from outside via the data terminal 23 is written into the memory cell array 11 via the I/O circuit 16, the serializer circuit 18, and the read/write amplifier 17.

The serializer circuit 18 may include circuitry that facilitates the conversion of parallel data to serial data and vice versa. One function of serializer circuit 18 may be to enable efficient and reliable transmission of data between systems with different clocking or data transmission requirements.

Serialization may include converting parallel data into a serial data stream. The parallel data, which may be represented as multiple bits transmitted simultaneously on separate lines, may be converted into a single bitstream. This conversion may allow for more manageable and efficient transmission of data over long distances, as it reduces the number of required transmission lines, reduces power consumption, and mitigates crosstalk and signal integrity issues. Serializer circuit 18 may achieve this by taking the parallel data, latching the parallel data with the help of a clock signal, and providing the data as a continuous stream of bits, serializer circuit 18 may provide the continuous stream of bits according to a clock signal (e.g., an internally generated clock signal that is based on LCLK).

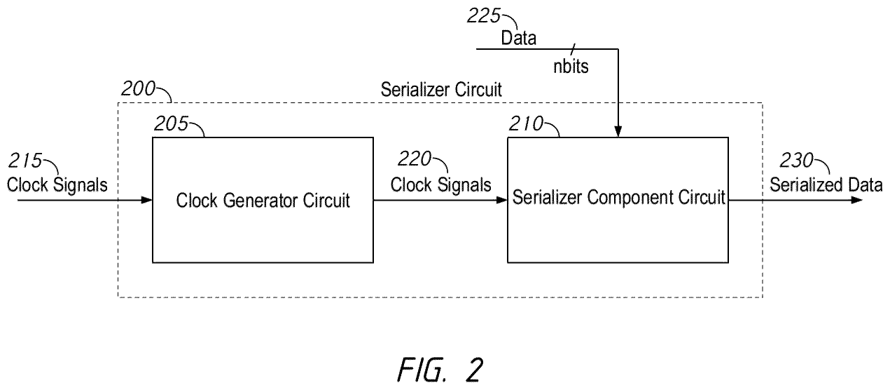

FIG. 2 is a block diagram of a serializer circuit 200 according to some embodiments of the disclosure. A memory device may include the serializer circuit 200 in some embodiments. serializer circuit 18 may include serializer circuit 200 in some embodiments of the disclosure. In some examples, serializer circuit 200 may include clock generator circuit 205, serializer component circuit 210, or both. Serializer circuit 200 may include additional or alternative circuitry in some cases.

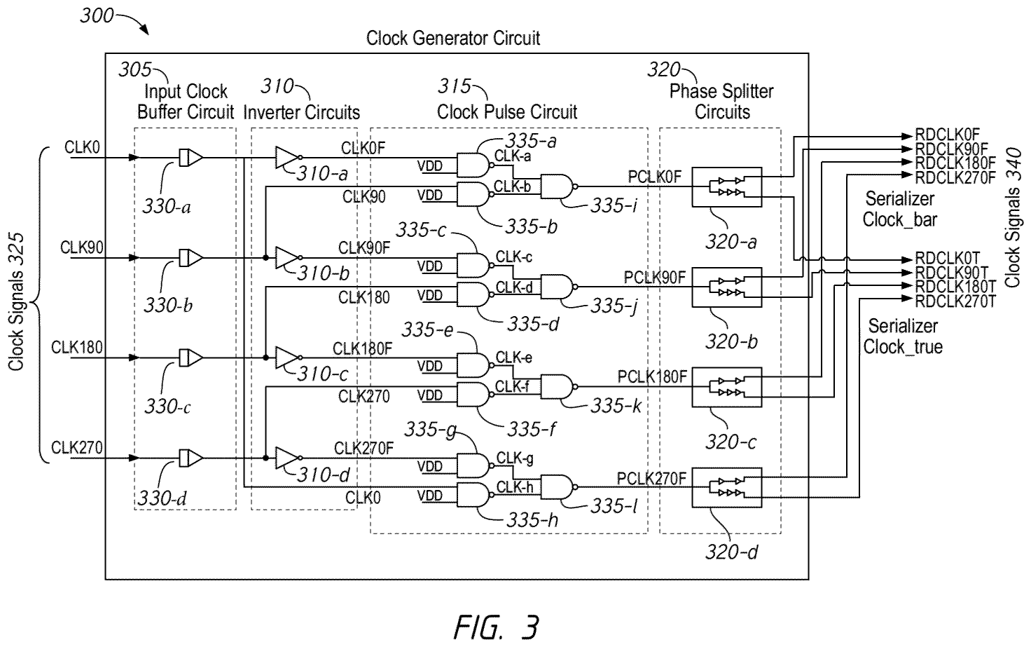

Clock generator circuit 205 may receive clock signals 215 from outside the serializer circuit 200. For example, clock generator 205 may receive one or more clock signals 215 from an internal clock generator (e.g., internal clock generator 35). Clock signals 215 may be a multi-phase clock signal (e.g., a 4-phase clock signal), and internal clock generator 35 may be a clock divider. Clock dividers may be described further in at least FIG. 6. Clock generator circuit 205 may include one or more circuit elements to generate clock signals 220 based on the clock signals 215. Clock generator circuit 205 may change (e.g., shorten) the pulse width of clock signals 215, among other operations. Clock generator circuit 205 may provide clock signals 220 to serializer component circuit 210. Clock generator 215 may be described in further detail in at least FIG. 3.

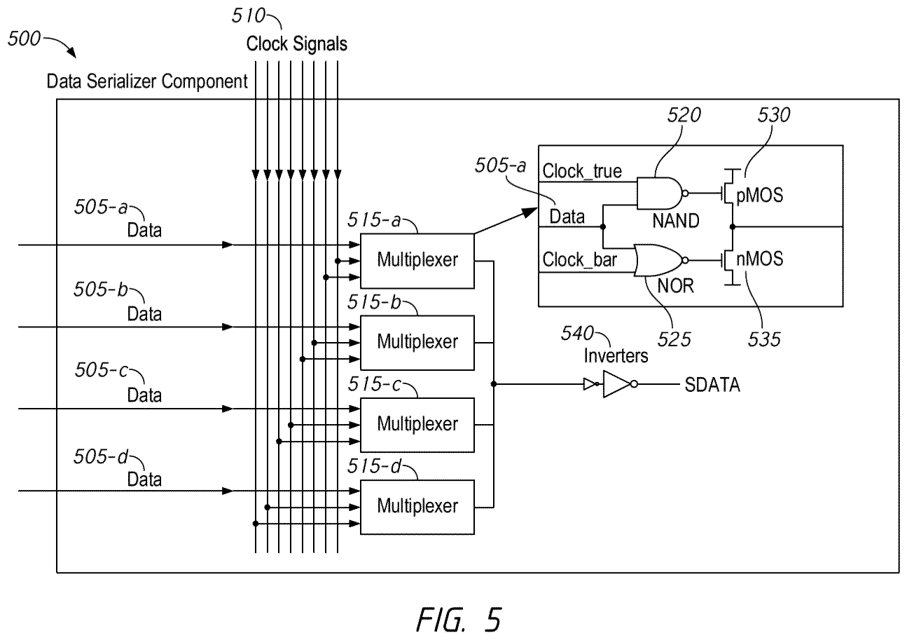

Serializer circuit 210 may receive data 225 from outside the serializer circuit 200. For example, serializer component circuit 210 may receive data 225 from a memory cell array, an I/O circuit, or both (e.g., memory cell array 11, I/O circuit 16, respectively). The data 225 is received by the serializer component circuit 210 in parallel, for example, n bits of data in parallel (e.g., n is a whole number greater than 0). Serializer circuit 210 may provide serialized data 230 based on the clock signals 220 and the data 225. For example, serializer component circuit 210 may use one or more multiplexers to align data 225 with clock signals 220 and selectively output serialized data 230 based on the timing of the clock signals 220. Serialized data 230 may include all or a portion of data 225. Serializer circuit 210 may be described in further detail in at least FIG. 5.

FIG. 3 is a schematic diagram of a clock generator circuit 300 according to some embodiments of the disclosure. In some examples, clock generator circuit 205 may include clock generator circuit 300. Clock generator circuit 300 may include input clock buffer circuit 305, inverter circuits 310, clock pulse circuit 315, and phase splitter circuits 320. Input clock buffer circuit 305 may be coupled to inverter circuits 310, which may be coupled to clock pulse circuit 315, which may be coupled to phase splitter circuits 320. Clock generator circuit 300 may include additional or alternative circuitry in some cases.

Input clock buffer circuit 305 may receive one or more clock signals 325. For example, input clock buffer circuit 305 may receive four clock signals with four different phases, where each phase is shifted by 90 degrees (or some other amount) relative to a previous phase. This may be referred to as 4-phase clock signals. Other numbers of clock signals with other numbers of phases may be received, and further explanation in the context of a 4-phase clock signal is merely one example. In the example of FIG. 3, input clock buffer circuit may receive four clock signals CLK0, CLK90, CLK180, and CLK270 shifted by 0 degrees, 90 degrees, 180 degrees, and 270 degrees respectively, moving from top to bottom (e.g., corresponding to drivers 330-a through 330-d).

Input clock buffer circuit 305 may include one or more drivers 330. Each driver 330 is configured to stabilize or preserve its respective input signal. In some examples, drivers 330 may amplify a weak input signal to a higher level, making it more resistant to noise and interference. This may help ensure that the output signal has correct voltage levels required for proper interpretation by downstream components. In some examples, drivers 330 may match the impedance of the source and load, reducing signal reflection, distortion, and attenuation, and improving overall signal quality. In some examples, drivers 330 may be buffers and may provide electrical isolation between the input and output signals, which may be useful to prevent the output signal from affecting the input. In some examples, drivers 330 may perform signal conditioning, such as filtering or level-shifting, to improve the quality of the output signal further. Input clock buffer circuit 305 may provide the clock signals to inverter circuits 310.

Inverter circuits 310 may include one or more inverters (NOT gates) 310-a, 310-b, 310-c, and 310-d configured to invert the clock level of the input (e.g., 0 to 1, or 1 to 0). Inverter circuits 310-a, 310-b, 310-c, and 310-d may respectively provide the inverted clock signals CLK0F, CLF90F, CLK180F, and CLK270F to clock pulse circuit 315. The input clock signals CLK0, CLK90, CLK180, and CLK270 may be provided to clock pulse circuit 315 in addition to the inverted clock signals CLK0F, CLF90F, CLK180F, and CLK270F. For example, both the input and output of the inverters are provided to the clock pulse circuit 315.

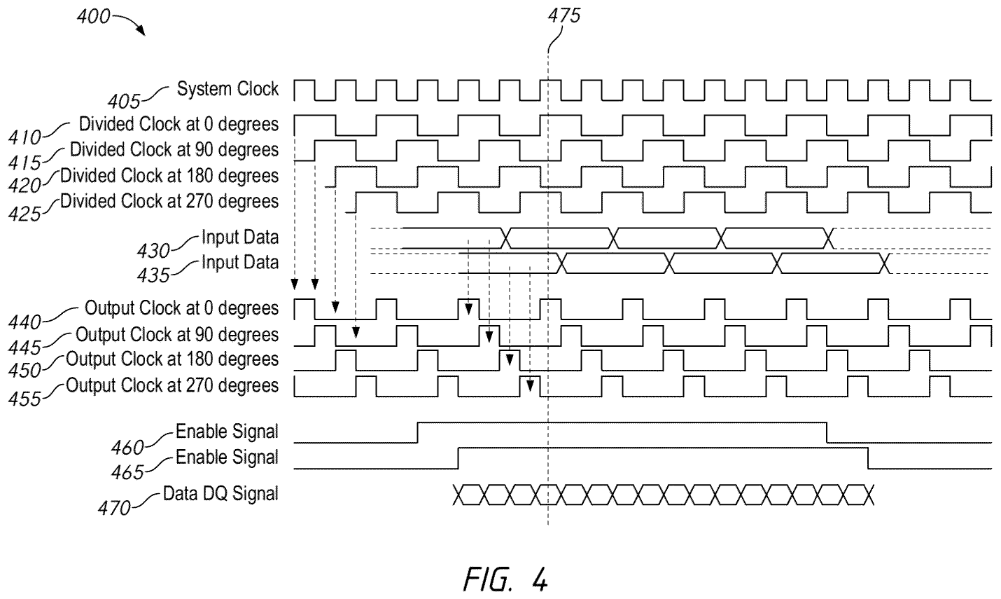

Clock pulse circuit 315 may include multiple NAND gates 335. Clock pulse circuit 315 may be configured to use the multiple NAND gates 335 to generate clock signals PCLK0F, PCLK90F. PCLK180F, and PCLK270F with a shorter pulse width. The clock pulse circuit 315 generates the clock signals PCLK0F, PCLK90F, PCLK180F, and PCLK270F with the shorter pulse width based on the states (e.g., logical high, low) of multiple (e.g., two) signals from the 4-phase clock signals. That is, for a given instance in time, the clock pulse circuit 315 identifies states of some of the 4-phase clock signals, and outputs a signal with a state based on those 4-phase clock signals. The clock pulse circuit 315 provides the output state through logical operations by the NAND gates 335. The clock pulse circuit 315 then repeats this process for each instance in time, effectively generating a new signal based on logical operations performed on the 4-phase clock signals. This process is mirrored for each of the 4-phase clock signals, so in total, four clock signals PCLK0F, PCLK90F, PCLK180F, and PCLK270F (e.g., clock pulses) may be output by the clock pulse circuit 315 based on the original 4-phase clock signals, but with shorter pulse widths. Further explanation of the clock pulse circuit 315 may be provided below, and additionally in FIG. 4, which features a timing diagram of the signals discussed.

It should be noted that FIG. 3, and the present disclosure as a whole, is not limited to 4-phase clock signals, or 4-phase clock signals where the signals are offset by 90 degree phase shifts, or any other particular configuration described herein. Rather, one skilled in the art would understand that the descriptions or illustrations provided herein may be modified to accommodate various other multi-phase clock signals (e.g., 2-phase, 3-phase, 6-phase), or amount of phase shift (e.g., 60 degrees, 120 degrees), and that corresponding modifications of the circuitry would be appropriate. Such configurations are merely examples of the present disclosure.

NAND gates 335-a through 335-h may each receive, at a first input, a signal indicative of a logical state of one of the clock signals 325 (e.g., CLK0, CLK90, CLK180, or CLK270) or the inverted state of the logical signal of one of the clock signals 325 (e.g., CLK0F, CLK90F, CLK180F, CLK270F, due to inverter circuits 310). NAND gates 335-a through 335-h may each additionally receive, at a second input, a logical high signal (e.g., provided by a logical high voltage level, VDD). NAND gates 335-a through 335-h may each perform a NAND operation on the states of the received signals to provide a respective output signal CLK-a, CLK-b, CLK-c, CLK-d, CLK-e. CLK-f, CLK-g, and CLK-h. For example, if NAND gate 335-a receives a logical low from the inverter 310-a of the inverter circuits 310, and receives a logical high at the second input (e.g., logical high voltage level VDD), the NAND operation may result in an output signal CLK-a having a logical high provided from the NAND gate 335-a.

NAND gates 335-i through 335-l may each receive, at respective first and second inputs, signals CLK-a through CLK-h indicative of logical states from both corresponding NAND gates 335-a through 335-h before it. For example, NAND gate 335-i may receive signals CLK-a and CLK-b indicative of logical states from NAND gate 335-a and 335-b. NAND gate 335-i may perform a NAND operation on the states of the received signals CLK-a and CLK-b to provide an output signal PCLK0F. For example, if NAND gate 335-i receives the signal CLK-a having a logical high from NAND gate 335-a at the first input, and receives the signal CLK-b having a logical high from NAND gate 335-b at the second input, the NAND operation may result in an output signal PCLK0F having a logical low, which is provided from the NAND gate 335-i.

Clock pulse circuit 315 may provide clock signals PCLK0F, PCLK90F, PCLK180F, and PCLK270F from the NAND gates 335-i through 335-l to respective phase splitter circuits 320-a, 320-b, 320-c, and 320-d. A phase splitter circuit may be an electronic circuit that takes an input signal and generates two or more output signals with different phase relationships. Phase splitters 320-a, 320-b, 320-c, and 320-d each include an input that splits into two lines. One line may include two inverters, and the other line may include three inverters. An inverter is a logic gate that receives an input signal and generates an output signal that is the inverse, or complement, of the input. Each inverter may provide an output signal that is complementary to the input signal. Other configurations for phase splitters are possible.

The line with two inverters may generate an output signal that has a same logical level relative to the input signal. The line with three inverters may generate an output signal that has a complementary logical level relative to the input signal. Although one line includes two inverters and the other line includes three inverters, in the phase splitter circuit the propagation delays of the one line and the other line are made equal. Thus, phase splitter circuits 320 each generate two output signals: one that has the same logical level as the input signal and another that has the complementary logical level as the input signal, and each of the output signals has the same propagation delay relative to the input signal. For example, the phase splitter circuit 320-a generates output signals RDCLK0F and RDCLK0T; the phase splitter circuit 320-b generates output signals RDCLK90F and RDCLK90T; the phase splitter circuit 320-c generates output signals RDCLK180F and RDCLK180T; and the phase splitter circuit 320-d generates output signals RDCLK270F and RDCLK270T. Each of these output signals are provided to a serializer component circuit (see FIG. 2) as clock signals 340.

FIG. 4 is a timing diagram 400 of clock signals according to some embodiments of the disclosure. While FIG. 4 depicts 4-phase clock signals, any other multi-phase clock signal may be applicable. Timing diagram 400 includes system clock 405, divided clock at 0 degrees 410, divided clock at 90 degrees 415, divided clock at 180 degrees 420, divided clock at 270 degrees 425, input data 430, input data 435, output clock at 0 degrees 440, output clock at 90 degrees 445, output clock at 180 degrees 450, output clock at 270 degrees 455, enable signal 460, enable signal 465, and data DQ signal 470.

System clock 405 may be a more general clock that the semiconductor device bases other clocks on (e.g., a main clock, external clock, reference clock). In some embodiments of the disclosure, the system clock 405 includes one or both of external clocks CK_t and CK_c. Divided clocks 410-425 may refer to the LCLK signal from FIG. 1 (e.g., from internal clock generator 35, which may include a clock divider), signals corresponding to clock signals 215 from FIG. 2, or the clock signals 325 (e.g., CLK0, CLK90, CLK180, CLK270) input to the input clock buffer circuit 305 from FIG. 3. Each of the four divided clock signals 410-425 may correspond to each clock signal of the 4-phase clock signal input to the input clock buffer circuit 305. Input data 430 and 435 may correspond to data 225 in FIG. 2 or the data provided to the serializer component in FIG. 5. Output clocks 440-455 may refer to the clock signals provided by the clock generator circuit 205 to the serializer component circuit 210 (clock signals 220). The output clocks 440-455 may also refer to clock signals provided by the clock generator 300 of FIG. 3, for example, RDCLK0T (440), RDCLK90T (445), RDCLK180T (450), and RDCLK270T (455). Enable signals 460 and 465 may be signals to enable the data output circuits included in an I/O circuit (e.g., I/O circuit 16 of FIG. 1) to transmit DQ signals 470 with proper timing. DQ signals 470 may represent the serialized data based on input data 430 and 435, and the serialized data is provided according to the timing of the generated output clocks 440-455 as illustrated in at least FIG. 5. In some examples, the pulse time for a pulse of an output clock 440-455 may be referred to as a unit interval (UI).

The following may be an example description of the propagation of a 4-phase clock signal (divided clocks 410-425) through clock generator circuit 300 to produce output clocks 440-455 in the context of timing diagram 400. The example description focuses on the portion of the clock signals at time 475.

At the input clock buffer circuit 305, each clock signal of the 4-phase clock signal may be provided to the input clock buffer circuit 305. Divided clock 410 may be provided to driver 330-a, divided clock 415 may be provided to driver 330-b, divided clock 420 may be provided to driver 330-c, and divided clock 425 may be provided to driver 330-d. These signals may continue to be referred to as divided clocks 410-425 as they propagate through the clock generator circuit 300 for ease of explanation, though these signals are changing throughout. Drivers 330 may stabilize, preserve, or otherwise “clean up” the divided clocks 410425.

Inverter circuits 310 invert the logic state of each of the divided clocks 410-425. At time 475, divided clock 410 is high, so the corresponding inverter inverts it to low. Divided clock 415 is low, so the corresponding inverter inverts it to high. Divided clock 420 is low, so the corresponding inverter inverts it to high. Divided clock 425 is high, so the corresponding inverter inverts it to low.

The inputs to the clock pulse circuit 315 may include both the inverted and the non-inverted signals. For example, NAND gate 335-a receives the inverted divided clock 410 (e.g., CLK0F), which is low. Low and high (the other input terminals for NAND gates 335-a through 335-h are kept high. e.g., provided a high logic level voltage VDD) results in high as the output CLK-a from NAND gate 335-a.

NAND gate 335-b receives the non-inverted divided clock 415 (e.g., CLK90), which is low. Low and high results in high as the output CLK-b from NAND gate 335-b.

NAND gate 335-c receives the inverted divided clock 415 (e.g., CLK90F), which is high. High and high results in low as the output CLK-c from NAND gate 335-c.

NAND gate 335-d receives the non-inverted divided clock 420 (CLK180), which is low. Low and high results in high as the output CLK-d from NAND gate 335-d.

NAND gate 335-e receives the inverted divided clock 420 (CLK180F), which is high. High and high results in low as the output CLK-e from NAND gate 335-e.

NAND gate 335-f receives the non-inverted divided clock 425 (CLK270), which is high. High and high results in low as the output CLK-f from NAND gate 335-f.

NAND gate 335-g receives the inverted divided clock 425 (CLK270F), which is low. Low and high results in high as the output CLK-g from NAND gate 335-g.

NAND gate 335-h receives the non-inverted divided clock 410 (CLK0), which is high. High and high results in low as the output CLK-h from NAND gate 335-h.

Moving on to NAND gates 335-i through 335-l. NAND gate 335-i receives high from NAND gate 335-a and high from NAND gate 335-b, resulting in low as the output PCLK0F from NAND gate 335-i.

NAND gate 335-j receives low from NAND gate 335-c and high from NAND gate 335-d, resulting in high as the output PCLK90F from NAND gate 335-j.

NAND gate 335-k receives low from NAND gate 335-e and low from NAND gate 335-f, resulting in high as the output PCLK180F from NAND gate 335-k.

NAND gate 335-l receives high from NAND gate 335-g and low from NAND gate 335-h, resulting in high as the output PCLK270 from NAND gate 335-l.

NAND gates 335-i through 335-l provide the outputs to phase splitter circuits 320. The false or bar outputs from the phase splitter circuits 320 correspond to the true clock signals for the serializer component (e.g., serializer clock_true; RDCLK0T, RDCLK90T, RDCLK180T, RDCLK270T), and the true outputs from the phase splitter circuits 320 correspond to the false or bar clock signals for the serializer component (e.g., serializer clock_bar; RDCLK0F, RDCLK90F, RDCLK180F, RDCLK270F). So, the serializer clock_true states are shown as output clocks 440-455 at time 475 in FIG. 4, which are the outputs that are provided to the serializer component circuit 210 (the serializer clock_bar signals are also provided to the serializer component circuit 210). The serializer clock_true states from top to bottom are high, low, low, low at time 475. These correspond with the 0, 90, 180, 270 phase shifted signals (divided clocks 410-425). Turning our attention to time 475 at FIG. 4, the states of output clock 440 is high, output clock 445 is low, output clock 450 is low, and output clock 455 is low. During this UI, data DQ 470 at time 475 is provided by serializer component circuit 210 as serialized data 230. As shown in FIG. 4, each bit of data is provided consecutively and is valid for one unit interval, or the pulse width of each of the respective output clocks 440-455. In this manner, the data 225 provided in parallel to a serializer component circuit is provided serially in a burst of data from the serializer component circuit based on the output clocks 440-455.

FIG. 5 is a block diagram of data serializer component 500 according to some embodiments of the disclosure. Serializer circuit 210 may include data serializer component 500. As such, data 505 may correspond to data 225. Clock signals 510 may correspond to clock signals 220 or clock signals 340 (e.g., RDCLK0F/T, RDCLK90F/T, RDCLK180F/T, RDCLK270F/T). Data serializer component 500 may include one or more multiplexers 515. As an example, multiplexer 515-a may include a NAND gate 520, a NOR gate 525, a p-channel transistor 530, and an n-channel transistor 535. In some cases, there may be two inverters 540 at the output of the multiplexers 515.

Data 505 is provided in parallel to a series of multiplexers 515, which select and combine the data based on clock signals 510. The multiplexers 515 serialize the parallel data and output the serialized data SDATA in a specific order as determined by the clock signals 510.

For example, focusing on multiplexer 515-a, data 505-a is provided as input to multiplexer 515-a, along with two clock signals from clock signals 510. The two clock signals for each multiplexer may correspond to a true and bar (e.g., false) version of the clock signal for a given phase. For example, multiplexer 515-a may receive output clock at 0 degrees 440 (referring to FIG. 4) true and bar (e.g., RDCLK0T and RDCLK0F). The data 505-a and the two clock signals interact within the multiplexer 515-a to produce the desired output while the output clocks are active. Internally, the data is split and provided to a NAND gate 520 and a NOR gate 525.

One of the two clock signals is being provided to the other input of the NAND gate 520 (e.g., the true version of the clock signal), while the other clock signal is being provided to the other input of the NOR gate 525 (e.g., the bar or false version of the clock signal). The NAND gate 520 and NOR gate 525 conditionally control the flow of data based on the clock signals. The output of the NAND gate 520 is coupled to the gate of a p-channel transistor 530, and the output of the NOR gate 525 is coupled to the gate of an n-channel transistor 535.

The p-channel transistor 530 may act as a switch that conducts when the output of the NAND gate 520 is low, while the n-channel transistor 535 conducts when the output of the NOR gate 525 is high. The source of the p-channel transistor 530 is coupled to the drain of the n-channel transistor 535, and the combined output is provided as the output of the multiplexer 515-a.

As the clock signals change, the NAND gate 520 and NOR gate 525 inside the multiplexer 515-a will produce different output states, effectively controlling the flow of data 505-a through the p-channel and n-channel transistors 530 and 535. This allows the multiplexer 515-a to selectively output data 505-a based on the timing of the respective active portions of the clock signals 510.

This process is repeated for each multiplexer 515 in the data serializer component 500, with each multiplexer output being combined to produce the final serialized output. The multiplexers 515 work in tandem to provide data 505 according to the clock signals 510, ensuring that the serialized data stream SDATA is generated with the desired timing and order. The output of serializer component 500 may correspond to data DQ signal 470 from FIG. 4.

By using the NAND 520, NOR 525, p-channel 530, and n-channel 535 components, the multiplexers 515 may control the flow of data 505 based on the clock signals 510. This allows the data serializer component 500 to generate a precisely timed serial output data stream SDATA.

FIG. 6 is a block diagram of a clock divider circuit 600 according to some embodiments of the disclosure. Internal clock generator 35 from FIG. 1 may include the clock divider circuit 600. The clock divider circuit 600 may include two separate D flip-flop circuits that work together to generate a 4-phase clock signal.

The first D flip-flop circuit 610 has an input system clock CLKt 605 (clock true), an output Qf that outputs CLK180 640 (180-degree phase shift), and another output Q that outputs CLK0 635 (0-degree phase shift). The input system clock CLKt may be based on, for example, an external clock CK_t. The output CLK0 635 is fed into inverter circuit 615, which is then connected back to the D input of D flip-flop circuit 610. When the clock input (CLKt 605) has a rising edge, D flip-flop circuit 610 captures the value at the D input (inverted CLK0 635) and transfers it to the Q output (CLK0 635). This configuration, with the inverter circuit 615 feedback loop, acts as a frequency divider, dividing the input clock frequency by 2 and generating two clock signals with a 180-degree phase shift from each other: CLK0 635 and CLK180 640.

The second D flip-flop circuit 625 has a similar configuration. It has an input CLKc 620 (complementary), and outputs CLK90 645 at Q and CLK270 650 at Qf. The input system clock CLKc may be based on, for example, an external clock CK_c. CLK90 645 is fed into inverter circuit 630, which is then connected back to the D input of D flip-flop circuit 625. When the clock input (CLKc 620) has a rising edge, D flip-flop circuit 625 captures the value at the D input (inverted CLK90 645) and transfers it to the Q output (CLK90 645). This setup also acts as a frequency divider, dividing the input clock frequency by 2 and generating two additional clock signals with a 180-degree phase shift from each other: CLK90 645 and CLK270 650.

By combining the outputs of D flip-flop circuit 610 and D flip-flop circuit 625, the clock divider is able to generate a 4-phase clock signal of CLK0 635, CLK90 645, CLK180 640, and CLK270 650. In some embodiments, the 4-phase clock signal of CLK0 635, CLK90 645, CLK180 640, and CLK270 650 may be provided as the clock signals 215 of FIG. 2, provided as the clock signals 325 of FIG. 3, and/or provided as the divided clocks 410-425 shown in FIG. 4. This set of 4-phase clock signals can be used to drive various digital systems, such as serializer circuit 18, serializer circuit 200, or any other digital system requiring precisely timed and phase-shifted clock signals. The clock divider circuit 600 may efficiently generate these 4-phase clock signals using the two D flip-flop circuits and their respective inverter feedback loops.

Other configurations for clock divider circuit 600 may be possible without departing from the general scope of a clock divider circuit. Some clock divider circuits may include counter circuits, shift register circuits, digital phase locked loops (PLLs), or the like.

Although various embodiments of the disclosure have been disclosed, it will be understood by those skilled in the art that the embodiments extend beyond the specifically disclosed embodiments to other alternative embodiments and/or uses and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying mode of the disclosed embodiments. Thus, it is intended that the scope of at least some of the present disclosure should not be limited by the particular disclosed embodiments described above.

From the foregoing it will be appreciated that, although specific embodiments of the disclosure have been described herein for purposes of illustration, various modifications may be made without deviating from the spirit and scope of the disclosure. Accordingly, the scope of the disclosure should not be limited any of the specific embodiments described herein.

What is claimed is:

1. An apparatus, comprising:
a plurality of inverter circuits configured to receive a corresponding plurality of clock signals and provide a plurality of inverted clock signals;
a clock pulse circuit configured to receive the plurality of inverted clock signals and the plurality of clock signals, and provide a plurality of clock pulses based at least in part on the plurality of inverted clock signals and the plurality of clock signals, the plurality of clock pulses having different phases;
a plurality of phase splitter circuits configured to receive the plurality of clock pulses, split the plurality of clock pulses into serializer clock signals, and provide the serializer clock signals; and
a serializer circuit configured to receive data and receive the serializer clock signals, and further configured to provide serialized data based at least in part on the serializer clock signals and the data.

2. The apparatus of claim 1, further comprising:
an input clock buffer circuit comprising a plurality of driver circuits and configured to receive the plurality of clock signals, stabilize the plurality of clock signals, and provide the plurality of clock signals to the plurality of inverter circuits.

3. The apparatus of claim 2, wherein the input clock buffer circuit receives the plurality of clock signals from a clock divider circuit.

4. The apparatus of claim 1, wherein the clock pulse circuit comprises a plurality of not and (NAND) gates configured to shorten the pulse widths of the plurality of clock signals and the plurality of inverted clock signals.

5. The apparatus of claim 4, wherein the plurality of NAND gates comprise a plurality of groups of NAND gates, and wherein each group of NAND gates comprise a same number of NAND gates.

6. The apparatus of claim 1, wherein the plurality of clock signals are each shifted in phase by a same amount relative to each other.

7. The apparatus of claim 1, wherein the serializer circuit comprises a plurality of multiplexers configured to selectively output the serialized data based at least in part on timing of the serializer clock signals.

8. The apparatus of claim 1, wherein at least one of the plurality of phase splitter circuits comprises a first line comprising two inverter circuits, and comprises a second line comprising three inverter circuits.

9. An apparatus, comprising:
a plurality of inverter circuits;
a first plurality of not and (NAND) logic gates, wherein corresponding outputs and inputs of the plurality of inverter circuits are coupled to corresponding inputs of the first plurality of NAND logic gates;
a second plurality of NAND logic gates, wherein corresponding outputs of the first plurality of NAND logic gates are coupled to corresponding inputs of the second plurality of NAND logic gates;
a plurality of phase splitter circuits, wherein corresponding outputs of the second plurality of NAND logic gates are coupled to corresponding inputs of the plurality of phase splitter circuits; and
a serializer circuit comprising a plurality of multiplexer circuits, wherein corresponding outputs of the phase splitter circuits are coupled to corresponding inputs of the plurality of multiplexer circuits.

10. The apparatus of claim 9, wherein there are twice as many of the first plurality of NAND logic gates as the second plurality of NAND logic gates.

11. The apparatus of claim 9, wherein an output of one NAND logic gate of the first plurality of NAND logic gates is coupled to an input of one NAND logic gate of the second plurality of NAND logic gates.

12. The apparatus of claim 9, wherein the serializer circuit is coupled to an input/output (L/O) circuit and coupled to a memory cell array.

13. The apparatus of claim 9, wherein at least one multiplexer circuit of the plurality of multiplexer circuits comprises a NAND logic gate, a not or (NOR) logic gate, a p-channel transistor, an n-channel transistor, or a combination thereof.

14. The apparatus of claim 9, further comprising:
a plurality of driver circuits, wherein corresponding outputs of the plurality of driver circuits are coupled to corresponding inputs of the plurality of inverter circuits.

15. The apparatus of claim 14, wherein inputs to the plurality of driver circuits are coupled to a clock divider circuit.

16. A method, comprising:
receiving a plurality of clock signals and a plurality of inverted clock signals;
providing a plurality of clock pulses based at least in part on the plurality of clock signals and the plurality of inverted clock signals, the plurality of clock pulses having different phases;
splitting the plurality of clock pulses into serializer clock signals;
receiving data; and
providing serialized data based at least in part on the serializer clock signals and the data.

17. The method of claim 16, wherein a pulse width of a clock pulse of the plurality of clock pulses is shorter than a pulse width of a clock signal of the plurality of clock signals.

18. The method of claim 16, further comprising:
stabilizing the plurality of clock pulses before the receiving the plurality of clock signals and the plurality of inverted clock signals.

19. The method of claim 16, wherein the plurality of clock signals are each shifted in phase by a same amount relative to each other.

20. The method of claim 16, further comprising:
selectively providing the serialized data based at least in part on the timing of the serializer clock signals.
